(19) United States
(12) Patent Application Publication
(10) Pub. No.: US 2002/0187651 A1
(43) Pub. Date: Dec. 12, 2002

(54) Method for making a semiconductor device

(76) Inventors: Kimberly G. Reid, Austin, TX (US); Hsing-Huang Tseng, Austin, TX (US); Julie C.H. Chang, Austin, TX (US); John R. Alvis, Austin, TX (US)

Correspondence Address: Motorola, Inc., Austin Intellectual Property Law Section, 7700 West Parmer Lane, MD: TX32/PL02, Austin, TX, 78729, US

(21) Appl. No.: 09/879,444

(22) Filed: Jun. 11, 2001

(51) Int. Cl. H01L 21/31; H01L 21/469

(52) U.S. Cl. 438/774; 438/786; 438/783; 438/790; 438/773; 438/769

(57) ABSTRACT

A technique for controlling the oxidation of silicon is achieved by applying low temperature ammonia prior to the oxidation. The result is that the subsequent oxidation of the silicon is at a slower oxidation rate and higher nitrogen content. The higher nitrogen content is particularly beneficial for a gate dielectric because it acts as somewhat of a boron barrier and provides additional resistance to unwanted oxidation. The result is transistors with improved gate dielectric thickness uniformity across a wafer for a tighter threshold voltage distribution, reduced shift in threshold voltage, and improved time to breakdown.

### FIELD OF THE INVENTION

This invention relates in general to a process for forming semiconductor devices, and more particularly to a process for forming semiconductor devices having silicon dioxide layers.

### RELATED ART

Silicon dioxide (SiO₂) is commonly used to form gate dielectrics in semiconductor devices. However, it is often difficult to control the growth of the SiO₂ layer because when exposed to oxygen, silicon will form an SiO₂ layer. High temperature pretreatment at temperatures greater than 800 degrees Celsius using NO or N₂O have been used. However, these pretreatments do not incorporate enough nitrogen into the silicon in order to substantially control SiO₂ growth. Therefore, NH₃ at temperatures greater than 800 degrees Celsius has been used. However, it has been found that using ammonia as a pretreatment degrades the quality of the subsequently formed SiO₂ layer due to hydrogen incorporation. Therefore, a need exists for a method to control SiO₂ growth without degrading the oxide quality.

### BRIEF DESCRIPTION OF THE DRAWINGS

The present invention is illustrated by way of example and not limitation in the accompanying figures, in which like references indicate similar elements, and in which:

FIG. 1 illustrates a cross-sectional view of a portion of a semiconductor substrate during an oxidation suppression process;

FIG. 2 illustrates a cross-sectional view of a portion of a semiconductor substrate after oxidation formation;

FIG. 3 illustrates a cross-sectional view of a portion of a semiconductor substrate after formation of a semiconductor device; and

FIG. 4 illustrates an annealing process of a semiconductor substrate in accordance with an embodiment of the present invention.

Skilled artisans appreciate that elements in the figures are illustrated for simplicity and clarity and have not necessarily been drawn to scale. For example, the dimensions of some of the elements in the figures may be exaggerated relative to other elements to help improve the understanding of the embodiments of the present invention.

### DETAILED DESCRIPTION OF THE DRAWINGS

As semiconductor devices shrink, the thickness of the gate dielectric decreases. Typically, the gate dielectric used is silicon dioxide. Therefore, as the thickness of the SiO₂ layer decreases, a need exists for controllable SiO₂ growth. Current pretreatments used have not been successful because they focus on high temperature annealing. Low temperature annealing has not been investigated because it is believed that annealing at a low temperature will not affect a top surface of a semiconductor substrate. In addition, it is very difficult to control temperatures less than about 350 degrees Celsius with current tools. However, a low temperature (less than 400 degrees Celsius) NH₃ anneal prior to oxidation allows for controllable SiO₂ growth. The anneal results in a higher concentration of nitrogen, a lower V_{T} shift, and an increased time dependent dielectric breakdown (TDDB) of the subsequently formed SiO₂. The invention is defined by the claims and is better understood by the embodiments described below with references to the figures. The present invention is not limited to the embodiments described.

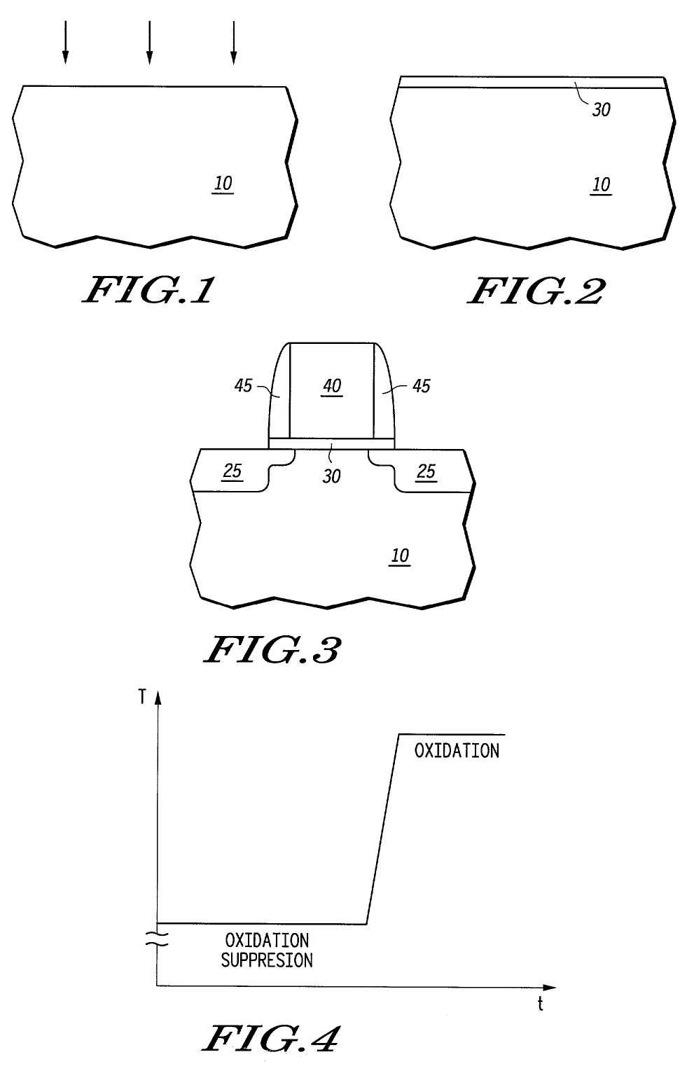

FIG. 1 includes an illustration of a cross-sectional view of a portion of semiconductor substrate 10. As used in the specification, a semiconductor substrate includes a monocrystalline semiconductor wafer, a semiconductor on insulator wafer, gallium arsenide, silicon germanium, germanium, or any other substrate used to form semiconductor devices. Semiconductor substrate 10 can also be described as a top surface of a silicon structure.

In accordance with the present invention, an NH₃ anneal is performed at temperatures less than approximately 400 degrees Celsius or, more specifically less than 350 degrees Celsius, on semiconductor substrate 10. If the subsequent formation of the SiO₂ gate oxide is formed by in situ steam generated (ISSG) oxidation, a pressure less than approximately 10 Torr, or, more specifically, a pressure between 3-7 Torr, is used. This NH₃ anneal process is performed for a time period of approximately 5 to 60 seconds or, more specifically, 25 seconds. In an embodiment, no oxygen is present during the NH₃ anneal to prevent or minimize SiO₂ growth during this process. In one embodiment, NO is substituted for NH₃. If NO is used, the temperature may a higher temperature, such as less than 1100 degrees Celsius.

Optionally, a second pretreatment anneal can be performed. However, this pretreatment is performed at a high temperature of approximately 800-1050 degrees Celsius using NO (nitric oxide). Alternately, N₂O (nitrous oxide) can also be used. In one embodiment, the anneal can be performed at 900 degrees Celsius. If the subsequently formed SiO₂ layer is formed using ISSG oxidation, the pressure for this NO anneal should be the same as the pressure for the ISSG process or more particularly about 3-7 Torr. It has been shown that 5.5 Torr has provided good results. This anneal is performed for approximately 5 to 20 seconds.

Turning to FIG. 2, gate oxide 30 is formed over semiconductor substrate 10. Gate oxide 30 can be formed by dry oxidation using NO, O₂, or O₂ and NO, as is known to one of ordinary skill in the art. In addition, gate oxide 30 can be formed by wet oxidation as is known to one of ordinary skill in the art. Alternately, a combination of wet and dry oxidation can be used. One type of wet oxidation, ISSG, is typically performed at temperatures between 800-1050 degrees Celsius at a pressure less than approximately 10 Torr or, more specifically, at about 3-7 Torr. It has been shown that 5.5 Torr has provided good results.

Optionally, a post-treatment anneal can be performed after oxidation. This post-treatment is performed at a high temperature of approximately 800-1050 degrees Celsius using NO. Alternately N₂O can be used. In one embodiment, the anneal can be performed at 900 degrees Celsius. If the subsequently formed SiO₂ layer is formed using ISSG oxidation, the pressure for this NO anneal should be the same as the pressure for the ISSG process or more particularly about 3-7 Torr. It has been shown that 5.5 Torr has provided good results. This anneal is performed for approximately 5 to 20 seconds.

After depositing the gate oxide 30 (and the post-treatment anneal, if performed), the gate oxide is patterned and a gate electrode or conductor 40 is formed. Typically, the gate electrode is polysilicon. However, other materials such as metals can be used. Sidewall spacers 45 are, typically, formed next to the gate electrode. Source and drain 25 are formed adjacent to the gate by ion implantation. This results in a channel between source and drain 25 under gate electrode 40. Typically, the formation of gate electrode 40, source and drain 25 requires patterning processes. Patterning of gate oxide 30 and formation of gate electrode 40, source and drain 25 and sidewall spacers 45 are conventional CMOS processes, known to one of ordinary skill in the art. The semiconductor device or transistor is shown in FIG. 3. Further CMOS processing, known to one of ordinary skill in the art, can be performed to form other devices or features.

Although the SiO₂ layer that has been described is used as a gate oxide, the low temperature NH₃ anneal can be used to control SiO₂ growth, in general, and is not limited to forming a gate oxide. In another embodiment, gate oxide 30 is a dielectric layer or oxide layer. For example, this process can be advantageous for suppressing the oxidation of silicon nanocrystals during manufacturing of quantum flash devices. FIG. 4 illustrates a temperature versus time graph for controllably forming an SiO₂ layer and is not limited to the embodiment described in FIGS. 1-3. An oxidation suppression process is formed on a silicon structure for a time period of approximately 25 seconds using ammonia at a low temperature, typically less than 400 degrees Celsius or, more specifically, less than 350 degrees Celsius. Subsequently, the temperature is increased for oxidation of the silicon or other processing that results in oxidation of the silicon.

What is claimed is:

1. A method for making a semiconductor device, comprising:
providing a semiconductor substrate having a top surface;
applying ammonia to the top surface at a temperature below 400 degrees Celsius; and
subsequent to applying the ammonia, oxidizing the top surface.

2. The method of claim 1, wherein the applying the ammonia occurs at a temperature below 350 degrees Celsius.

3. The method of claim 2, wherein the oxidizing the top surface comprises:
applying nitric oxide; and
applying steam.

4. The method of claim 1, wherein the oxidizing the top surface comprises:
applying nitric oxide; and
applying steam.

5. The method of claim 4, wherein the applying the steam occurs after the applying the nitric oxide.

6. The method of claim 5, wherein the applying the steam occurs at a temperature above 800 degrees Celsius.

7. The method of claim 6, wherein the applying the ammonia occurs at a temperature below 350 degrees Celsius.

8. The method of claim 7, wherein the oxidizing the top surface forms a dielectric layer, further comprising:
forming a conductor over the dielectric layer;
patterning the conductor and the dielectric layer to form a gate and a gate oxide, wherein the gate is over the gate oxide; and
forming a source and drain adjacent to the gate to leave a channel between the source and the drain and under the gate

9. The method of claim 1, wherein the oxidizing the top surface comprises applying nitric oxide and wherein the ammonia is applied at a temperature under 350 degrees Celsius.

10. The method of claim 9, wherein the oxidizing the top surface forms a dielectric layer, further comprising:
forming a conductor over the dielectric layer;
patterning the conductor and the dielectric layer to form a gate and a gate oxide, wherein the gate is over the gate oxide; and
forming a source and drain adjacent to the gate to leave a channel between the source and the drain and under the gate.

11. The method of claim 1, wherein the oxidizing the top surface comprises applying nitrous oxide.

12. A method of making a semiconductor device, comprising:
providing a silicon structure;
applying ammonia to the silicon structure at a temperature below 400 degrees Celsius; and
exposing the silicon structure to oxygen after applying the ammonia.

13. The method of claim 12, wherein the silicon structure is a top surface of a silicon substrate and the oxygen is contained in nitric oxide.

14. A method of making a semiconductor device, comprising:
providing a structure;
applying ammonia, while excluding a presence of oxygen, to the structure at a temperature below 400 degrees Celsius; and
exposing the structure to oxygen after applying the ammonia.

15. The method of claim 14, wherein the structure is a top surface of a silicon substrate and the oxygen is contained in nitric oxide.

16. The method of claim 14, wherein the structure is a silicon structure.

17. The method of claim 16, wherein the silicon structure is a top surface of a silicon substrate and wherein the exposing the structure to oxygen causes formation of an oxide layer on the top surface.

18. The method of claim 17, wherein the exposing the structure to oxygen comprises:
applying nitric oxide to the silicon structure; and
applying steam to the silicon structure.

19. The method of claim 18, further comprising.
forming a conductor over the oxide layer;
patterning the conductor and the oxide layer to form a gate and a gate oxide, wherein the gate is over the gate oxide; and
forming a source and drain adjacent to the gate to leave a channel between the source and the drain and under the gate.

20. The semiconductor device of claim 16, wherein the exposing the structure to oxygen comprises applying nitrous oxide to the silicon structure.

21. The semiconductor device of claim 20, wherein the applying the ammonia is for a time period less than one minute.
